(19) United States
(12) Patent Application Publication
(10) Pub. No.: US 2021/0193964 A1
(43) Pub. Date: Jun. 24, 2021

(54) Display Apparatus

(71) Applicant: LG Display Co., Ltd., Seoul (KR)

(72) Inventors: Dohyung KIM, Paju-si (KR); MinJoo KANG, Paju-si (KR)

(21) Appl. No.: 17/122,993

(22) Filed: Dec. 15, 2020

(30) Foreign Application Priority Data
Dec. 20, 2019 (KR) 10-2019-0172132

(51) Int. Cl. H01L 51/52

(52) U.S. Cl. CPC H01L 51/5256

(57) ABSTRACT

A display apparatus in which an encapsulation function is enhanced, and thus, the penetration of external water and oxygen are minimized A display apparatus includes a substrate, a light emitting device provided on the substrate, a first adhesive layer provided on the light emitting device to cover the light emitting device, and a first encapsulation substrate provided on the first adhesive layer. A side surface of the first adhesive layer is covered by the first encapsulation substrate.

### CROSS-REFERENCE TO RELATED APPLICATIONS

This application claims the benefit of the Korean Patent Application No. 10-2019-0172132 filed on Dec. 20, 2019, which is hereby incorporated by reference as if fully set forth herein.

### BACKGROUND

### Field of the Invention

The present disclosure relates to a display apparatus.

### Discussion of the Related Art

With the advancement of information-oriented society, various requirements for display apparatuses for displaying an image are increasing. Therefore, various display apparatuses such as liquid crystal display (LCD) apparatuses, plasma display panels (PDPs), and organic light emitting display apparatuses are being used recently.

Organic light emitting display apparatuses among display apparatuses are self-emitting display apparatuses and do not need a separate backlight. Therefore, in comparison with LCD apparatuses, the organic light emitting display apparatuses may be implemented to be lightweight and thin and to have low power consumption. Also, the organic light emitting display apparatuses are driven with a direct current (DC) low voltage, have a fast response time, and have low manufacturing cost.

However, organic light emitting devices are easily degraded by external causes such as external water and oxygen. In order to prevent such a problem, an encapsulation layer is formed on an organic light emitting device so as to prevent external water and oxygen from penetrating into the organic light emitting device.

The encapsulation layer may be formed to include an organic layer, for example, an adhesive layer provided on the organic light emitting device. In this case, a side surface of the encapsulation layer may be exposed to the outside, and external water and oxygen may flow in through a side surface of the organic layer. The external water and oxygen flowing in through a side surface of the organic layer may damage the organic light emitting device to cause a defect in a display apparatus.

### SUMMARY

Accordingly, the present disclosure is directed to providing a display apparatus that substantially obviates one or more problems due to limitations and disadvantages of the related art.

An aspect of the present disclosure is directed to providing a display apparatus in which an encapsulation function is enhanced, and thus, the penetration of external water and oxygen is minimized.

Additional advantages and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

To achieve these and other advantages and in accordance with the purpose of the disclosure, as embodied and broadly described herein, there is provided a display apparatus including a substrate, a light emitting device provided on the substrate, a first adhesive layer provided on the light emitting device to cover the light emitting device, and a first encapsulation substrate provided on the first adhesive layer, wherein a side surface of the first adhesive layer is covered by the first encapsulation substrate.

It is to be understood that both the foregoing general description and the following detailed description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a cross-sectional view illustrating a display apparatus according to a first embodiment of the present disclosure;

FIG. 2 is a cross-sectional view illustrating a display apparatus according to a second embodiment of the present disclosure;

FIG. 3 is a plan view illustrating a plurality of grooves formed in a first encapsulation substrate, according to the second embodiment of the present disclosure;

FIG. 4 is a plan view illustrating a modification example of the plurality of grooves shown in FIG. 3;

FIG. 5 is a cross-sectional view illustrating an example of the plurality of grooves taken along line I-I′ of FIG. 3; and

FIGS. 6A to 6D are cross-sectional views illustrating a process of forming a first adhesive layer and a first encapsulation substrate, according to a preferable example of the first embodiment of the present disclosure.

### DETAILED DESCRIPTION OF THE DISCLOSURE

Reference will now be made in detail to the exemplary embodiments of the present disclosure, examples of which are illustrated in the accompanying drawings. Wherever possible, the same reference numbers will be used throughout the drawings to refer to the same or like parts.

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Further, the present disclosure is only defined by scopes of claims.

A shape, a size, a ratio, an angle, and a number disclosed in the drawings for describing embodiments of the present disclosure are merely an example, and thus, the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted. In a case where ‘comprise’, ‘have’, and ‘include’ described in the present specification are used, another part may be added unless ‘only-’ is used. The terms of a singular form may include plural forms unless referred to the contrary.

In construing an element, the element is construed as including an error range although there is no explicit description.

In describing a position relationship, for example, when a position relation between two parts is described as ‘on˜’, ‘over˜’, ‘under˜’ and ‘next˜’, one or more other parts may be disposed between the two parts unless ‘just’ or ‘direct’ is used.

In describing a time relationship, for example, when the temporal order is described as ‘after˜’, ‘subsequent˜’, ‘next˜’, and ‘before˜’ a case which is not continuous may be included unless ‘just’ or ‘direct’ is used.

It will be understood that, although the terms “first”, “second”, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

A first horizontal axis direction, a second horizontal axis direction, and a vertical axis direction should not be construed as only a geometric relationship where a relationship therebetween is vertical, and may denote having a broader directionality within a scope where elements of the present disclosure operate functionally.

An X axis direction, a Y axis direction, and a Z axis direction should not be construed as only a geometric relationship where a relationship therebetween is vertical, and may denote having a broader directionality within a scope where elements of the present disclosure operate functionally.

In describing the elements of the present disclosure, terms such as first, second, A, B, (a), (b), etc., may be used. Such terms are used for merely discriminating the corresponding elements from other elements and the corresponding elements are not limited in their essence, sequence, or precedence by the terms. It will be understood that when an element or layer is referred to as being “on” or “connected to” another element or layer, it can be directly on or directly connected to the other element or layer, or intervening elements or layers may be present. Also, it should be understood that when one element is disposed on or under another element, this may denote a case where the elements are disposed to directly contact each other, but may denote that the elements are disposed without directly contacting each other.

The term “at least one” should be understood as including any and all combinations of one or more of the associated listed elements. For example, the meaning of “at least one of a first element, a second element, and a third element” denotes the combination of all elements proposed from two or more of the first element, the second element, and the third element as well as the first element, the second element, or the third element.

Features of various embodiments of the present disclosure may be partially or overall coupled to or combined with each other, and may be variously inter-operated with each other and driven technically as those skilled in the art can sufficiently understand. The embodiments of the present disclosure may be carried out independently from each other, or may be carried out together in co-dependent relationship.

Hereinafter, embodiments of the present disclosure will be described in detail with reference to the accompanying drawings. In adding reference numerals to elements of each of the drawings, although the same elements are illustrated in other drawings, like reference numerals may refer to like elements. Also, for convenience of description, a scale of each of elements illustrated in the accompanying drawings differs from a real scale, and thus, is not limited to a scale illustrated in the drawings.

Hereinafter, embodiments of the present disclosure will be described in detail with reference to the accompanying drawings.

### First Embodiment

FIG. 1 is a cross-sectional view illustrating a display apparatus according to a first embodiment of the present disclosure. Hereinafter, an example where a display apparatus according to an embodiment of the present disclosure is an organic light emitting display apparatus will be mainly described, but the present disclosure is not limited thereto.

Referring to FIG. 1, the display apparatus according to the first embodiment of the present disclosure may include a substrate 100, a circuit device layer 200, a light emitting device 300, a first adhesive layer 410, and a first encapsulation substrate 510.

The substrate 100 may be a plastic film, a glass substrate, or a silicon wafer substrate formed through a semiconductor process. The substrate 100 may include a transparent material, or may include an opaque material.

The display apparatus according to the first embodiment of the present disclosure may be implemented as a bottom emission type where emitted light travels toward the substrate. In this case, the substrate 100 may include a transparent material. Also, the display apparatus according to the first embodiment of the present disclosure may be implemented as a top emission type where emitted light travels away from the substrate. In this case, the substrate 100 may include an opaque material.

The circuit device layer 200 may be formed on the substrate 100. A circuit device including various signal lines, a thin film transistor (TFT), and a capacitor may be included in the circuit device layer 200. The signal lines may include a gate line, a data line, a power line, and a reference line, and the TFT may include a switching TFT, a driving TFT, and a sensing TFT.

The switching TFT may be turned on based on a gate signal supplied through the gate line and may transfer a data voltage, supplied through the data line, to the driving TFT.

The driving TFT may be turned on based on the data voltage supplied through the switching TFT and may generate a data current from power supplied through the power line to supply the data current to the light emitting device.

The sensing TFT may sense a threshold voltage deviation of the driving TFT causing the degradation in image quality and may transfer a current of the driving TFT to the reference line in response to a sensing control signal supplied through the gate line of the sensing TFT or a separate sensing line.

The capacitor may hold the data voltage supplied through the driving TFT during one frame and may be connected to each of a gate terminal and a source terminal of the driving TFT.

A contact hole may be provided in the circuit device layer 200, and thus, the source terminal or a drain terminal of the driving TFT may be exposed through the contact hole.

The light emitting device 300 may be formed on the circuit device layer 200. The light emitting device 300 may include a first electrode 310, a bank 320, a light emitting layer 330, and a second electrode 340.

The first electrode 310 may be formed on the circuit device layer 200. The first electrode 310 may be connected to the source terminal or the drain terminal of the driving TFT through the contact hole. The first electrode 310 may include a transparent material, or may include an opaque material.

In a case where the display apparatus according to the first embodiment of the present disclosure is implemented as the bottom emission type, the first electrode 310 may include a transparent conductive material (TCO), such as indium tin oxide (ITO) or indium zinc oxide (IZO), or a semi-transmissive conductive material such as magnesium (Mg), silver (Ag), or an alloy of Mg and Ag.

In a case where the display apparatus according to the first embodiment of the present disclosure is implemented as the top emission type, the first electrode 310 may include a metal material, which is high in reflectance, such as a stacked structure (titanium/aluminum/titanium (Ti/Al/Ti)) of Al and Ti, a stacked structure (ITO/Al/ITO) of Al and ITO, an APC alloy, or a stacked structure (ITO/APC/ITO) of an APC alloy and ITO. In this case, the APC alloy may be an alloy of silver (Ag), palladium (Pb), and copper (Cu).

The bank 320 may be formed on the first electrode 310 and may define an emission area. An electric field may not be formed between the first electrode 310 and the second electrode 340, in a region where the bank 320 is formed, and thus, light may not be emitted.

The bank 320 may be implemented as an organic layer such as acryl resin, epoxy resin, phenolic resin, polyamide resin, or polyimide resin. Alternatively, the bank 320 may be implemented as an inorganic layer such as silicon nitride, aluminum nitride, zirconium nitride, titanium nitride, hafnium nitride, tantalum nitride, silicon oxide, aluminum oxide, or titanium oxide.

The light emitting layer 330 may be formed on the first electrode 310. The light emitting layer 330 may be formed on the bank 340.

The light emitting layer 330 may include a hole transporting layer, an organic light emitting layer, and an electron transporting layer. In this case, when a voltage is applied to the first electrode 310 and the second electrode 340, a hole and an electron may respectively move to the light emitting layer 330 through the hole transporting layer and the electron transporting layer and may be combined in the light emitting layer 330 to emit light.

The light emitting layer 330 may include a white light emitting layer emitting white light. Alternatively, the light emitting layer 330 may include at least one of a red light emitting layer emitting red light, a green light emitting layer emitting green light, and a blue light emitting layer emitting blue light.

The second electrode 340 may be formed on the light emitting layer 330. The second electrode 340 may include a transparent material, or may include an opaque material.

In a case where the display apparatus according to the first embodiment of the present disclosure is implemented as the bottom emission type, the second electrode 340 may include a metal material, which is high in reflectance, such as a stacked structure (titanium/aluminum/titanium (Ti/Al/Ti)) of Al and Ti, a stacked structure (ITO/Al/ITO) of Al and ITO, an APC alloy, or a stacked structure (ITO/APC/ITO) of an APC alloy and ITO. In this case, the APC alloy may be an alloy of silver (Ag), palladium (Pb), and copper (Cu).

In a case where the display apparatus according to the first embodiment of the present disclosure is implemented as the top emission type, the second electrode 340 may include a transparent conductive material (TCO), such as indium tin oxide (ITO) or indium zinc oxide (IZO), or a semi-transmissive conductive material such as magnesium (Mg), silver (Ag), or an alloy of Mg and Ag.

A capping layer 350 may be formed on the second electrode 340 and may protect the second electrode 340. The capping layer 350 may be implemented as a multilayer where one or more inorganic layers of silicon oxide (SiOx), silicon nitride (SiNx), and/or silicon oxynitride (SiON) are alternately stacked.

The first adhesive layer 410 may be provided on the capping layer 350 and the light emitting device 300 and may be formed to cover the capping layer and the light emitting device 300. Moreover, the first adhesive layer 410 may be formed to contact the substrate 100. Therefore, the first adhesive layer 410 functions as an encapsulation layer.

According to the first embodiment of the present disclosure, a side surface 410a of the first adhesive layer 410 may be covered by the first encapsulation substrate 510. Accordingly, at least one portion of the side surface 410a of the first adhesive layer 410 is not exposed to the outside and the penetration of external water and oxygen may be reduced, and an encapsulation function of the display apparatus may be enhanced.

Hereinafter, a preferable example according to the first embodiment of the present disclosure where the side surface of the first adhesive layer is convex will be mainly described. As shown in the cross section of FIG. 1, a side surface 410a of the first adhesive layer 410 may be formed to be convex, and a top surface 410b of the first adhesive layer 410 may be flat or convex. More specifically, a reference line L, which is a virtual rectilinear line that passes through a center C of the light emitting device 300 and is vertical to the substrate 100, may be set. In this case, a distance between the reference line L and a contact point 410c between the side surface 410a and the top surface 410b of the first adhesive layer 410 may be set to be less than a distance between the reference line L and a contact point 410e between the side surface 410a of the first adhesive layer 410 and the substrate 100. Also, a distance between the reference line L and a peak end 410d of the side surface 410a of the first adhesive layer 410 may be set to be greater than a distance between the reference line L and the contact point 410e between the side surface 410a of the first adhesive layer 410 and the substrate 100. Accordingly, a region between the peak end 410d of the side surface 410a of the first adhesive layer 410 and the contact point 410e between the side surface 410a of the first adhesive layer 410 and the substrate 100 may have a shape which is rolled toward the reference line L. It should be noted that, the contact point 410c refers to a contact line between the side surface and the top surface of the first adhesive layer, and the contact point 410e refers to a contact line between the side surface of the first adhesive layer and the substrate 100, extending in a direction perpendicular to the cross section shown in FIG. 1.

The first adhesive layer 410 may include an organic material.

The first adhesive layer 410 may include acryl resin, epoxy resin, phenolic resin, polyamide resin, polyimide resin, or olefin.

The first adhesive layer 410 may be formed by a vapor deposition process, a printing process, or a slit coating process, which uses an organic material, but is not limited thereto and the first adhesive layer 410 may be formed by an ink-jet process.

The first adhesive layer 410 may include a water-absorbing material and a hydrogen-absorbing material. The water-absorbing material and the hydrogen-absorbing material may each be one of alkali metal, alkali earth metal, an inert compound of alkali metals, and an inert compound of alkali earth metals. Accordingly, water flowing in from the outside and hydrogen occurring in the inside may be absorbed by the first adhesive layer 410, and thus, the light emitting device 300 may be prevented from being damaged by water and hydrogen.

The first encapsulation substrate 510 may be provided on the first adhesive layer 410 and cover the side surface 410a of the first adhesive layer 410.

The first encapsulation substrate 510 may contact the first adhesive layer 410 and may be bent along the side surface 410a of the first adhesive layer 410. In detail, the first encapsulation substrate 510 may contact the side surface 410a of the first adhesive layer 410 as well as the top surface 410b of the first adhesive layer 410, and thus, an exposed portion of the side surface 410a of the first adhesive layer 410 through which external water and oxygen penetrate into the display apparatus may be reduced. Accordingly, the penetration of external water and oxygen may be minimized, and an encapsulation function of the display apparatus may be enhanced.

The first encapsulation substrate 510 may cover all of the side surface 410a and the top surface 410b of the first adhesive layer 410. Therefore, the first encapsulation substrate 510 may contact the substrate 100. Also, the side surface 410a and the top surface 410b of the first adhesive layer 410 may be completely occluded by the first encapsulation substrate 510, and thus, may not be exposed to the outside.

Alternatively, the first encapsulation substrate 510 may cover all of the top surface 410b of the first adhesive layer 410, but may expose a portion of the side surface 410a of the first adhesive layer 410. Therefore, the first encapsulation substrate 510 may not contact the substrate 100. Also, a region, which is adjacent to the substrate 100, of the side surface 410a of the first adhesive layer 410 may not be occluded by the first encapsulation substrate 510 and may be exposed to the outside.

The first encapsulation substrate 510 may be formed by attaching metal, on which a rolling process has been performed, to an upper portion of the first adhesive layer 410. Also, the first encapsulation substrate 510 may be formed of a thin film including at least one metal of aluminum (Al), copper (Cu), and invar, but is not limited thereto.

The above description relates to a preferable example where the side surface of the first adhesive layer is convex, but the present disclosure is not limited thereto. For example, it is contemplated the side surface of the first adhesive layer may be flat or concave or irregular, as long as the side surface of the first adhesive layer is covered by the first encapsulation substrate. Thus, detailed description with respect to other separate shapes of the side surface of the first adhesive layer is omitted.

### Second Embodiment

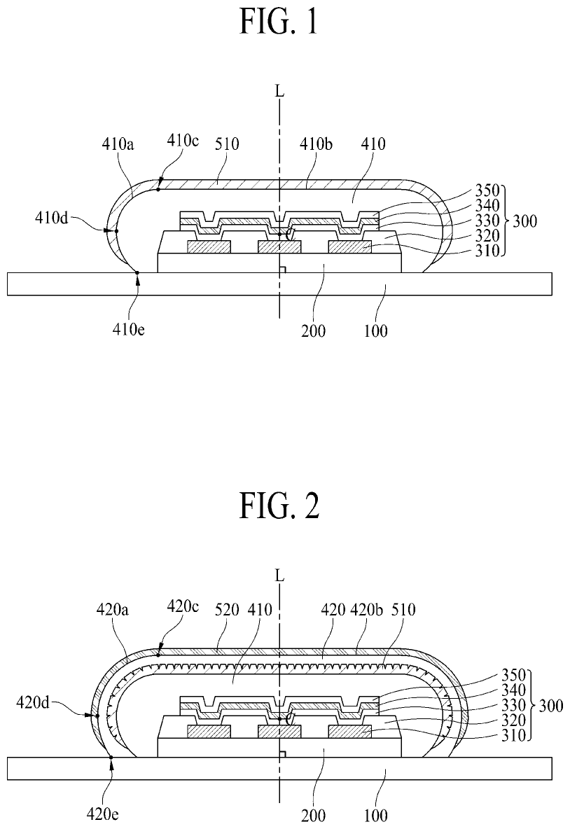

FIG. 2 is a cross-sectional view illustrating a display apparatus according to a second embodiment of the present disclosure.

Referring to FIG. 2, the display apparatus according to the second embodiment of the present disclosure may include a substrate 100, a circuit device layer 200, a light emitting device 300, a first adhesive layer 410, a second adhesive layer 420, a first encapsulation substrate 510, and a second encapsulation substrate 520.

The substrate 100, the circuit device layer 200, the light emitting device 300, the first adhesive layer 410, and the first encapsulation substrate 510 configuring the display apparatus according to the second embodiment of the present disclosure may be substantially the same as the substrate 100, the circuit device layer 200, the light emitting device 300, the first adhesive layer 410, and the first encapsulation substrate 510 configuring the display apparatus according to the second embodiment of the present disclosure, and thus, their detailed description are omitted.

Hereinafter, an example where the display apparatus according to the second embodiment of the present disclosure is an organic light emitting display apparatus will be mainly described, but the present disclosure is not limited thereto.

The second adhesive layer 420 may be provided on the first encapsulation substrate 510 and may be formed to cover the first encapsulation substrate 510 and contact the substrate 100. Also, when a side surface 410a of the first adhesive layer 410 is exposed by the first encapsulation substrate 510, the second adhesive layer 420 may be formed to cover all of the exposed portion of the first adhesive layer 410 and the first encapsulation substrate 510. Accordingly, the first adhesive layer 410 may not be exposed to the outside.

Hereinafter, a preferable example according to the second embodiment of the present disclosure where the side surface of the second adhesive layer is convex will be mainly described. As shown in the cross section of FIG. 2, a side surface 420a of the second adhesive layer 420 may be formed to be convex, and a top surface 420b of the second adhesive layer 420 may be flat or convex. More specifically, a distance between a reference line L and a contact point 420c between the side surface 420a and a top surface 420b of the second adhesive layer 420 may be set to be less than a distance between the reference line L and a contact point 420e between the side surface 420a of the second adhesive layer 420 and the substrate 100. Also, a distance between the reference line L and a peak end 420d of the side surface 420a of the second adhesive layer 420 may be set to be greater than a distance between the reference line L and the contact point 420e between the side surface 420a of the second adhesive layer 420 and the substrate 100. Accordingly, a region between the peak end 420d of the side surface 420a of the second adhesive layer 420 and the contact point 420e between the side surface 420a of the second adhesive layer 420 and the substrate 100 may have a shape which is rolled toward the reference line L. similarly as the contact points 410c, 410e, the contact points 420c, 420e each refer to a contact line, and their detailed description is omitted.

The second adhesive layer 420 may include an organic material.

The second adhesive layer 420 may include acryl resin, epoxy resin, phenolic resin, polyamide resin, polyimide resin, or olefin.

The second adhesive layer 420 may be formed by a vapor deposition process, a printing process, or a slit coating process, which uses an organic material, but is not limited thereto and the second adhesive layer 420 may be formed by an ink-jet process.

The second adhesive layer 420 may include a water-absorbing material and a hydrogen-absorbing material.

The second adhesive layer 420 may include the water-absorbing material. The water-absorbing material may be one of alkali metal, alkali earth metal, an inert compound of alkali metals, and an inert compound of alkali earth metals. Accordingly, water flowing in from the outside may be absorbed by the second adhesive layer 420, and thus, the light emitting device 300 may be prevented from being damaged by water and hydrogen.

Because the display apparatus according to the second embodiment of the present disclosure further includes the second adhesive layer 420, water and oxygen flowing in from the outside may be distributed and diffused to the second adhesive layer 420 and even to the first adhesive layer 410. That is, not all of water and oxygen flowing in from the outside may be diffused to the first adhesive layer 410 only. Accordingly, compared with the first embodiment of the present disclosure, as the amount of external water and oxygen diffused to the first adhesive layer 410 may be decreased, the final amount of water and oxygen penetrating into the light emitting device 300 covered by the first adhesive layer 410 may also decrease. Accordingly, the damage of the light emitting device 300 caused by external water and oxygen may be minimized.

The second encapsulation substrate 520 may be provided on the second adhesive layer 420 and cover the side surface 420c of the second adhesive layer 420.

The second encapsulation substrate 520 may contact the second adhesive layer 420 and may be bent along the side surface 420a of the second adhesive layer 420. In detail, the second encapsulation substrate 520 may contact the side surface 420a of the second adhesive layer 420 as well as the top surface 420b of the second adhesive layer 420, and thus, an exposed portion of the second adhesive layer 420 through which external water and oxygen penetrates into the display apparatus may be reduced. Also, the first adhesive layer 410 and the first encapsulation substrate 510 may not be externally exposed by the second adhesive layer 420 and the second encapsulation substrate 520, and thus, compared with the first embodiment, a speed at which external water and oxygen penetrate into the display apparatus may be more reduced, thereby enhancing an encapsulation function of the display apparatus.

The second encapsulation substrate 520 may cover all of the side surface 420a and the top surface 420b of the second adhesive layer 420. Therefore, the second encapsulation substrate 520 may contact the substrate 100. Also, the side surface 420a and the top surface 420b of the second adhesive layer 420 may be completely occluded by the second encapsulation substrate 520, and thus, may not be exposed to the outside.

Alternatively, the second encapsulation substrate 520 may cover all of the top surface 420b of the second adhesive layer 420, but may expose a portion of the side surface 420a of the second adhesive layer 420. Therefore, the second encapsulation substrate 520 may not contact the substrate 100. Also, a region, which is adjacent to the substrate 100, of the side surface 420a of the second adhesive layer 420 may not be occluded by the second encapsulation substrate 520 and may be exposed to the outside.

The second encapsulation substrate 520 may be formed by attaching metal, on which a rolling process has been performed, to an upper portion of the second adhesive layer 420. Also, the second encapsulation substrate 520 may be formed of a thin film including at least one metal of aluminum (Al), copper (Cu), and invar, but is not limited thereto.

The above description relates to a preferable example where the side surface of the second adhesive layer is convex, but the present disclosure is not limited thereto. For example, it is contemplated the side surface of the second adhesive layer may be flat or concave or irregular, as long as the side surface of the second adhesive layer is covered by the second encapsulation substrate. Thus, detailed description with respect to other separate shapes of the side surface of the second adhesive layer is omitted.

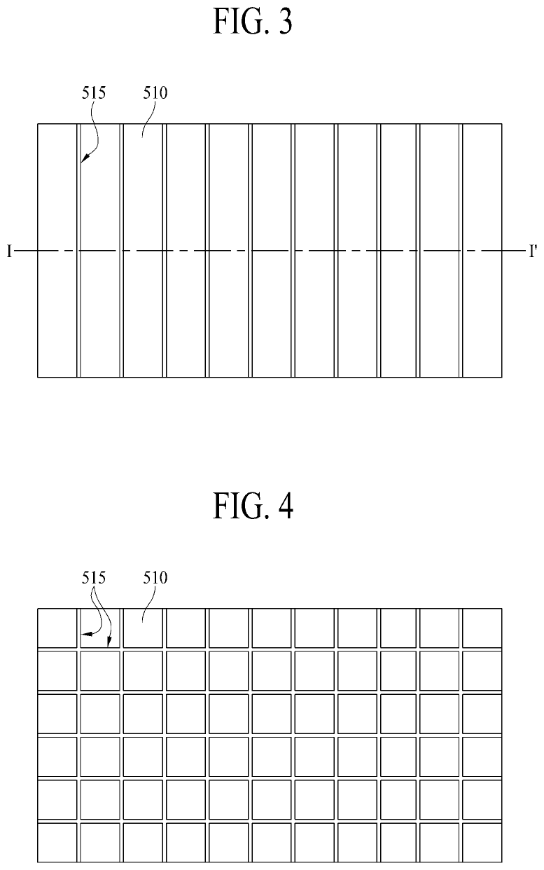

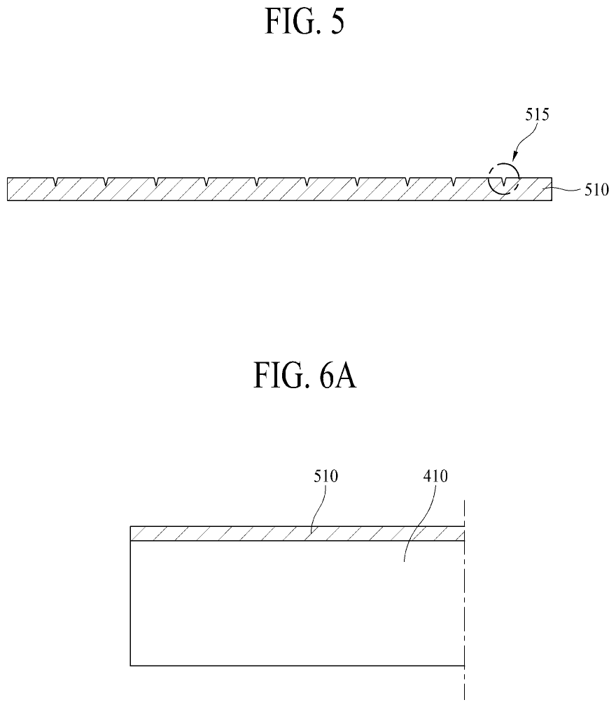

FIG. 3 is a plan view illustrating a plurality of grooves 515 formed in a first encapsulation substrate 510, according to the second embodiment of the present disclosure, FIG. 4 is a plan view illustrating a modification example of the plurality of grooves shown in FIG. 3, and FIG. 5 is a cross-sectional view illustrating an example of the plurality of grooves taken along line I-I′ of FIG. 3.

The display apparatus according to the second embodiment of the present disclosure may include a plurality of grooves 515 formed in an upper portion of the first encapsulation substrate 510 contacting the second adhesive layer 420.

As illustrated in FIG. 3, each of the plurality of grooves 515 may be formed in the form of a rectilinear line, and the rectilinear line may be formed in a first direction which is parallel to a contact line (i.e., the contact point 420c as shown in FIG. 2) between the side surface and the top surface of the first encapsulation substrate 510 when the first encapsulation substrate 510 is bent. Accordingly, when the first encapsulation substrate 510 is bent in a horizontal direction along a side surface of the first adhesive layer 410, stress occurring in an upper portion of the first encapsulation substrate 510 may decrease.

Moreover, as illustrated in FIG. 4, the plurality of grooves 515 may include a plurality of grooves 515 formed in a rectilinear shape in a first direction and a plurality of grooves 515 formed in a rectilinear shape in a second direction perpendicular to the first direction. Therefore, compared with the first encapsulation substrate 510 of FIG. 3, the plurality of grooves 515 formed in a rectilinear shape in the second direction perpendicular to the first direction may be further provided, and thus, when the first encapsulation substrate 510 is bent at an upper side, an lower side, a left side and a right side thereof along a side surface of the first adhesive layer 410, stress occurring in the upper portion of the first encapsulation substrate 510 may be more reduced.

Moreover, the plurality of grooves 515 may be formed in an area of the upper portion of the first encapsulation substrate 510 in which bending occurs, not in all of the upper portion of the first encapsulation substrate 510.

Moreover, as illustrated in FIG. 5, a cross-sectional surface of each of the plurality of grooves 515 may be formed in a V-shape, but is not limited thereto. In a case where the cross-sectional surface of each of the plurality of grooves 515 is formed in a V-shape, when the first encapsulation substrate 510 is bent, stress occurring in the upper portion of the first encapsulation substrate 510 may be reduced, and moreover, external water may be prevented from penetrating through the plurality of grooves 515 of the first encapsulation substrates 510.

Additionally, in a case where a plurality of grooves 515 are formed in an upper portion of the second encapsulation substrate 520, each of the plurality of grooves 515 may be a path through which external water and oxygen penetrate into the display apparatus, due to an external impact applied to the second encapsulation substrate 520. Accordingly, in order to prevent such a problem, a groove may not be formed in a top surface of the second encapsulation substrate 520.

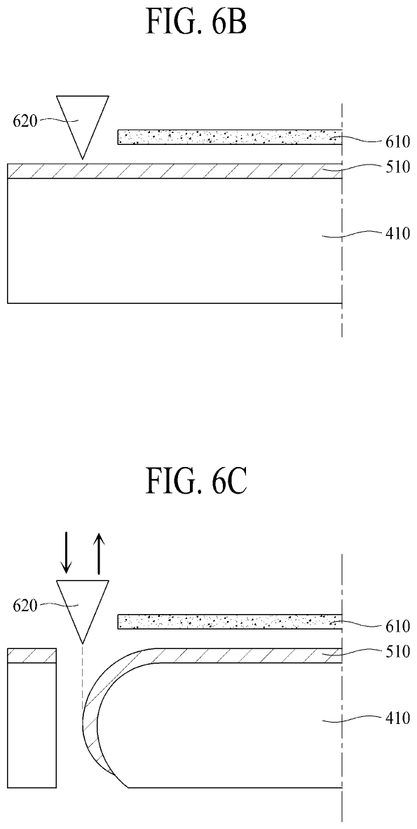

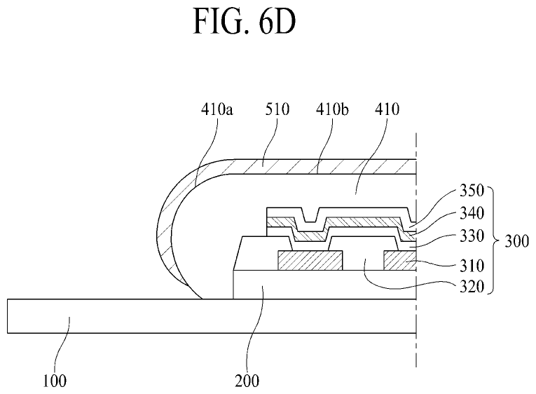

FIGS. 6A to 6D are cross-sectional views illustrating a process of forming a first adhesive layer 410 and a first encapsulation substrate 510, according to the first embodiment of the present disclosure. Hereinafter, a preferable example of the process for forming the first adhesive layer and the first encapsulation substrate where the side surface of the first adhesive layer is convex will be mainly described, but the present disclosure is not limited thereto.

As illustrated in FIG. 6A, the first encapsulation substrate 510 may be provided on the first adhesive layer 410. A protection film (not shown) for protecting the first adhesive layer 410 may be attached on a lower portion of the first adhesive layer 410. The protection film (not shown) may be formed to include polyethylene terephthalate (PET), but is not limited thereto. The first encapsulation substrate 510 may be formed by attaching metal, on which a rolling process has been performed, to an upper portion of the first adhesive layer 410.

As illustrated in FIG. 6B, a fixed frame 610 and a blade 620 may be disposed. The fixed frame 610 and the blade 620 may be disposed at positions apart from an upper portion of the first encapsulation substrate 510 in a vertical direction. The fixed frame 610 may overlap the upper portion of the first encapsulation substrate 510, and a portion of an edge of the upper portion of the first encapsulation substrate 510 may be exposed. The blade 620 may be disposed at a position apart from an end of the fixed frame 610.

As illustrated in FIG. 6C, the blade 620 may upward and downward move to cut the first adhesive layer 410 and the first encapsulation substrate 510. At this time, a region which does not overlap the fixed frame 610 may be separated from each of the first adhesive layer 410 and the first encapsulation substrate 510. As a result, a side surface 410a of the first adhesive layer 410 may be formed to be convex, and a top surface 410b of the first adhesive layer 410 may be flat or convex. Also, the first encapsulation substrate 510 may contact the first adhesive layer 410 and may be formed to be bent along the side surface 410a of the second adhesive layer 410.

As illustrated in FIG. 6D, the fixed frame 610 and the blade 620 may be removed. Also, the first adhesive layer 410 and the first encapsulation substrate 510 separated from each other by the blade 620 may be removed. Also, a substrate 100 with a circuit device layer 200 and a light emitting device 300 formed therein may be bonded to the first adhesive layer 410 and the first encapsulation substrate 510, thereby manufacturing a display apparatus.

The present disclosure is not limited to the above process and many other processes may be used for forming the first adhesive layer and the first encapsulation substrate with other separate shapes of side surfaces, such as, flat, concave and irregular, for example, by virtue of different shapes and motion manners of the blade. Moreover, the first encapsulation substrate may be separately formed with a corresponding shape to the side surface of the first adhesive layer and then assembled with the first adhesive layer.

A process for forming a first adhesive layer 410, a first encapsulation substrate 510, a second adhesive layer 420 and a second encapsulation substrate 520 according to the second embodiment of the present disclosure may be similar to the process with respect to the first embodiment, and thus its detailed description is omitted.

According to the present disclosure, a first encapsulation substrate may contact a first adhesive layer and cover a side surface of the first adhesive layer, and thus, the penetration of external water and oxygen through the side surface of the first adhesive layer may be prevented, thereby enhancing an encapsulation function of a display apparatus.

Moreover, according to the present disclosure, a second adhesive layer may be further provided and may block and absorb water and oxygen flowing in from the outside, and thus, the amount of water and oxygen flowing in through the first adhesive layer may be reduced, thereby decreasing the amount of water and oxygen penetrating into an organic light emitting device.

Moreover, according to the present disclosure, the second adhesive layer and a second encapsulation substrate may be further provided, and a plurality of grooves may be formed in an upper portion of the first encapsulation substrate contacting the second adhesive layer, thereby decreasing a stress occurring in the upper portion of the first encapsulation substrate when the first encapsulation substrate is bent.

The above-described feature, structure, and effect of the present disclosure are included in at least one embodiment of the present disclosure, but are not limited to only one embodiment. Furthermore, the feature, structure, and effect described in at least one embodiment of the present disclosure may be implemented through combination or modification of other embodiments by those skilled in the art. Therefore, content associated with the combination and modification should be construed as being within the scope of the present disclosure.

It will be apparent to those skilled in the art that various modifications and variations can be made in the present disclosure without departing from the spirit or scope of the disclosures. Thus, it is intended that the present disclosure covers the modifications and variations of this disclosure provided they come within the scope of the appended claims and their equivalents.

What is claimed is:

1. A display apparatus comprising:
a substrate;
a light emitting device provided on the substrate;
a first adhesive layer provided on the light emitting device to cover the light emitting device; and
a first encapsulation substrate provided on the first adhesive layer,
wherein a side surface of the first adhesive layer is covered by the first encapsulation substrate.

2. The display apparatus of claim 1, wherein the side surface of the first adhesive layer is convex, flat, concave or irregular, and the first encapsulation substrate contacts the first adhesive layer and is bent along the side surface of the first adhesive layer.

3. The display apparatus of claim 1, wherein the first encapsulation substrate covers all of a top surface and the side surface of the first adhesive layer.

4. The display apparatus of claim 1, wherein the first encapsulation substrate exposes a portion of a region, which is adjacent to the substrate, of the side surface of the first adhesive layer and covers all of a top surface of the first adhesive layer.

5. The display apparatus of claim 1, wherein the first encapsulation substrate contacts the substrate.

6. The display apparatus of claim 1, wherein, when a reference line, which is a virtual rectilinear line which passes through a center of the light emitting device and is vertical to the substrate, is set, a distance between the reference line and a contact point between the side surface and a top surface of the first adhesive layer is less than a distance between the reference line and a contact point between the side surface of the first adhesive layer and the substrate in a cross section of the display apparatus.

7. The display apparatus of claim 1, wherein, when a reference line, which is a virtual rectilinear line which passes through a center of the light emitting device and is vertical to the substrate, is set, a distance between the reference line and a peak end of the side surface of the first adhesive layer is greater than a distance between the reference line and a contact point between the side surface of the first adhesive layer and the substrate in a cross section of the display apparatus.

8. The display apparatus of claim 1, wherein the first encapsulation substrate is formed of a thin film including at least one metal of aluminum (Al), copper (Cu), and invar.

9. The display apparatus of claim 1, wherein the first adhesive layer comprises a water-absorbing material and a hydrogen-absorbing material.

10. The display apparatus of claim 1, further comprising:
a second adhesive layer covering the first encapsulation substrate; and
a second encapsulation substrate provided on the second adhesive layer,
wherein a side surface of the second adhesive layer is covered by the second encapsulation substrate.

11. The display apparatus of claim 10, wherein the side surface of the second adhesive layer is convex, flat, concave or irregular, and the second encapsulation substrate contacts the second adhesive layer and is bent along the side surface of the second adhesive layer.

12. The display apparatus of claim 10, wherein the second encapsulation substrate covers all of a top surface and the side surface of the second adhesive layer.

13. The display apparatus of claim 10, wherein the second encapsulation substrate exposes a portion of a region, which is adjacent to the substrate, of the side surface of the second adhesive layer and covers all of a top surface of the second adhesive layer.

14. The display apparatus of claim 10, wherein the second encapsulation substrate contacts the substrate.

15. The display apparatus of claim 10, wherein the first encapsulation substrate comprises a plurality of grooves formed in an upper portion thereof contacting the second adhesive layer.

16. The display apparatus of claim 15, wherein each of the plurality of grooves is formed in the form of a rectilinear line, and the rectilinear line is formed in a first direction which is parallel to a contact line of a side surface and a top surface of the first encapsulation substrate in a cross section of the display apparatus when the first encapsulation substrate is bent.

17. The display apparatus of claim 16, wherein the first encapsulation substrate further comprises a plurality of grooves formed in a rectilinear shape perpendicular to the first direction.

18. The display apparatus of claim 15, wherein each of the plurality of grooves comprises a cross-sectional surface having a V-shape.
